(19) United States
(12) Patent Application Publication
(10) Pub. No.: US 2004/0012405 A1
(43) Pub. Date: Jan. 22, 2004

(54) Probe card with full wafer contact configuration

(75) Inventors: S. J. Cheng, Hsinchu (TW); An-Hong Liu, Tainan City (TW); Yeong-Her Wang, Tainan City (TW); Yuan-Ping Tseng, Hsinchu (TW); Y. J. Lee, Tainan (TW)

Correspondence Address: DENNISON, SCHULTZ & DOUGHERTY, 612 Crystal Square 4, 1745 Jefferson Davis Highway, Arlington, VA, 22202-3417, US

(73) Assignees: ChipMOS Technologies (Bermuda) Ltd.; ChipMOS TECHNOLOGIES INC.

(21) Appl. No.: 10/198,119

(22) Filed: Jul. 19, 2002

(51) Int. Cl. G01R 31/02

(52) U.S. Cl. 324/761

(57) ABSTRACT

A probe card with full wafer contact configuration comprises a back plate and a plurality of modular multiplayer ceramic wiring boards coplanarly mounted on the back plate. The total size of the modular multilayer ceramic wiring boards is larger than that of a wafer under test in order to fully contact all the bonding pads of the wafer under test. The modular multilayer ceramic wiring boards can be manufactured separately according to various locations. Thus, the manufacturing cost is reduced and yield is improved and lead time is shortened.

### FIELD OF THE INVENTION

The present invention relates to a probe card with a full wafer contact configuration, particularly to a probe card with a plurality of modular multilayer ceramic wiring boards mounted on a back plate. The probe card will fully contact the bonding pads of the wafer under test (WUT).

### BACKGROUND OF THE INVENTION

Conventionally, the semiconductor chips are mass-produced on a wafer such as 6″ 8″ or 12″ wafer. A wafer may comprise hundreds to thousands of chips. When a wafer is under chip probing test or burn-in test, a probe card set up in a test head of a tester will contact the wafer. Conventionally the probe card can only contacts the wafer partially, covers only few or several tens of chips at a time. After every chip probing, the wafer and/or the probe card need to be moved to next probing site. The readjustments during every chip probing will thus decrease the testing efficiency and increase testing time.

A probe card that can fully contact the electrodes of the wafer under test was revealed in U.S. Pat. No. 6,215,321 entitled “PROBE CARD FOR WAFER-LEVEL MEASUREMENT, MULTILAYER CERAMIC WIRING BOARD, AND FABRICATING METHODS THEREFOR”. The probe card 20 can fully contact the pad electrodes 26 formed on the wafer 25 mounted on the wafer tray 28, as shown in FIG. 5. The probe card 20 comprises: a multilayer wiring board 21; a polyimide thin film 22; and an anisotropic conductive rubber 23. The multilayer wiring board 21 was co-fired ceramics with multilayer circuits and vias. An anisotropic conductive rubber 23 made of silicone rubber 23a was integrated on one of the surfaces of the multilayer wiring board 21. The an isotropic conductive rubber 23, also comprising of conductive particles 23b, is an elastic member for providing electrical connections between a thin-film wiring layer 29 formed on the multilayer wiring board 21 and the bumps 22b of the polyimide thin film 22. The bumps 22b can fully contact the bonding pads 26 on the wafer 25, so the size of the modular multilayer ceramic wiring board 21 should be larger than the wafer 25. Malfunction in any one of the electrical circuits or vias in manufacturing will fail this large-size of multilayer ceramic wiring board 21, so the manufacturing yield is reduced, i.e., the cost of multilayer ceramic wiring board 21 is very high. There are many difficulties in manufacturing the modular multilayer wiring board 21.

### SUMMARY OF THE INVENTION

The main purpose of the present invention is to supply a probe card with full wafer contact configuration comprises a back plate and a plurality of modular multilayer ceramic wiring boards coplanarly mounted on the back plate. The total size of the modular multilayer ceramic wiring boards is larger than that of the wafer under test. The modular multilayer ceramic wiring boards can be manufactured separately according to the various locations. The quality of manufacturing, assembly and application of the probe card with full wafer contact configuration are assured in the present invention.

In accordance with the present invention, a probe card with full wafer contact configuration comprises a plurality of modular multilayer ceramic wiring boards, interconnecting with each other by horizontal or vertical slots, mounted on a same back plate. The total size of the modular multilayer ceramic wiring boards is larger than a wafer under test. A single-layer wiring cover substrate is formed to contact the other sides of the modular multilayer ceramic wiring boards, such as ceramic, thin-film or silicon substrates. The cover substrate has a plurality of electrical contact points, such as probe needles or conductive bumps manufactured on a surface of the substrate to fully contact the bonding pads of the wafer under test. The electrical contact points of the substrate will provide electrical connections to the back plate for chip probing or burn-in test.

### DESCRIPTION OF THE DRAWINGS

FIG. 1 is a three-dimensional layout of a probe card with full wafer contact configuration according to the present invention;

FIG. 2 is a cross-sectional view of a probe card with full wafer contact configuration according to the present invention;

FIG. 3 is a cross-sectional view showing the fully contact between the wafer under test and the probe card according to the present invention;

FIG. 4 is a cross-sectional view showing the fully contact between another probe card with full wafer contact configuration and another larger bonding pad pitch wafer according to the present invention; and

FIG. 5 is a cross-sectional view of a probe card according to the U.S. Pat. No. 6,215,321 entitled “PROBE CARD FOR WAFER-LEVEL MEASUREMENT, MULTILAYER CERAMIC WIRING BOARD, AND FABRICATING METHODS THEREFOR”.

### DETAIL DESCRIPTION OF THE INVENTION

Please referring to the drawings attached, the present invention will be described by means of an embodiment below.

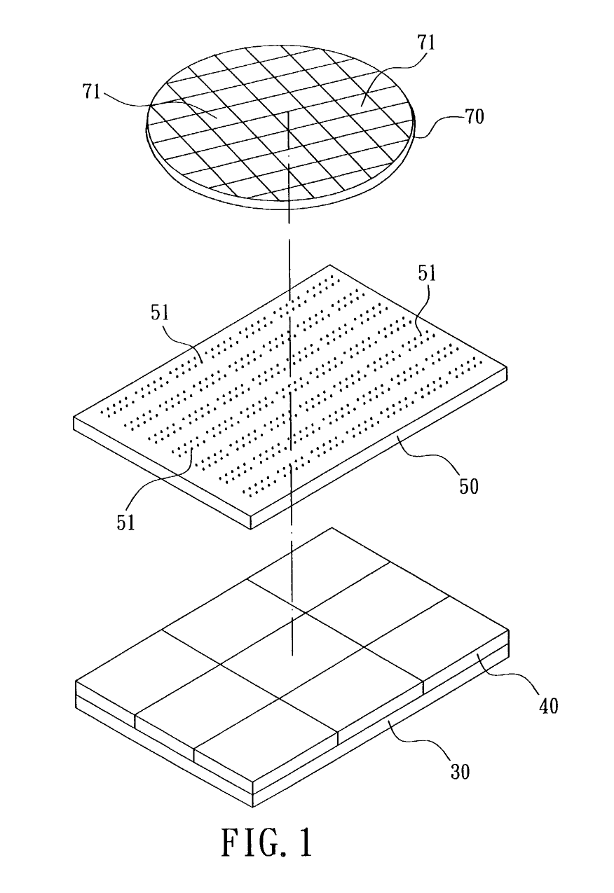

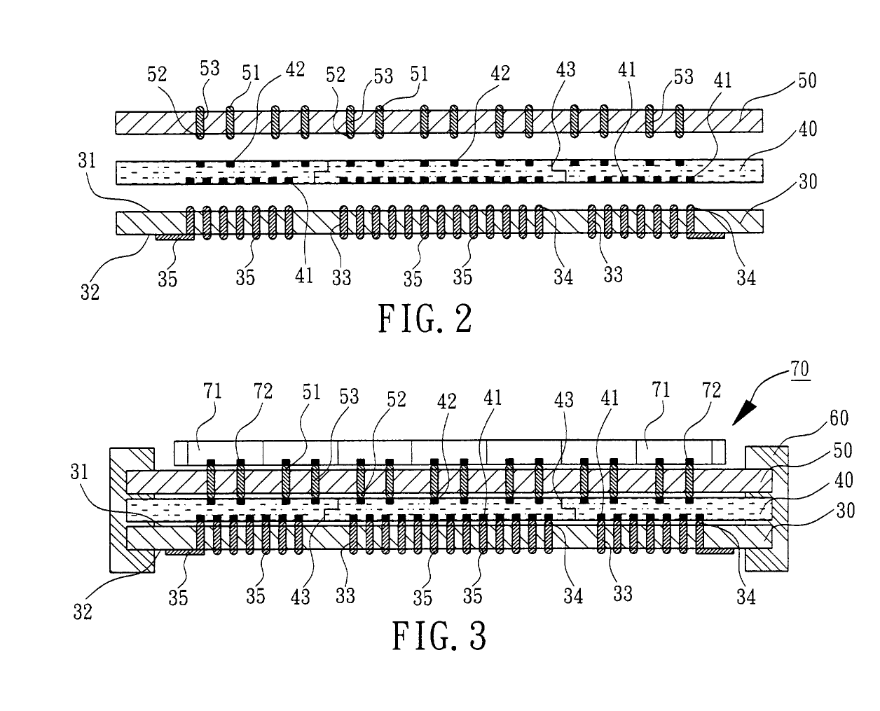

As shown in FIGS. 1 and 2, the probe card with full wafer contact configuration comprises: a back plate 30, a plurality of modular multilayer ceramic wiring board 40, and a cover substrate 50 to fully contact a wafer 70 under test. Conventionally, there are many chips, such as memory, logic, ASIC, micro-processors or micro-controllers and so on, are embodied in the wafer 70 under test.

As shown in FIG. 2, the back plate 30 is a ceramic board, with a size larger than the wafer 70 under test. The back plate 30 has a first surface 31, a second surface 32 and a plurality of vias 33 which electrically connect the first and second surfaces 31,32. The first surface 31 has several contacting pads 34, connecting directly to first contacting pads 41 formed on the modular multilayer ceramic wiring boards 40. The second surface 32 also has many contacting pads 35 (or metal fingers) formed on the edge which electrically connect to corresponding the contacting pads 34 of the first surface 31 by means of the vias 33. The simple structure of the back plate 30, only formed with dual or a few layers of wiring patterns, will ensure an improved yield during manufacturing and a reduction of manufacturing cost.

As shown in FIGS. 1 and 2, the plurality of modular multilayer ceramic wiring boards 40 are embodied in the back plate 30 on a same plane, and the total size of the modular multilayer ceramic wiring boards 40 is larger than the wafer 70 under test. Horizontal or vertical slots are formed on the edge 43 of each modular multilayer ceramic wiring board 40 for interconnection between modular multilayer ceramic wiring boards 40. Each modular multilayer ceramic wiring board 40, with multilayer of wiring patterns, including multilayer of circuits and vias (not show in the figure), is electrically connected to the first contacting pads 41 and the corresponding second contacting pads 42 on opposing surfaces. The modular multilayer ceramic wiring board 40 also may include electrical components, such as inductors and capacitors. On the bottom surface of the modular multilayer ceramic wiring board 40 is formed with the first contacting pads 41 and is designed according to the contacting pads 34 of the first surface 31 on the back plate 30. The second contacting pads 42 are formed on the top surfaces of the modular multilayer ceramic wiring boards 40 which have the same contacting pad layout as the contacting pads 52 on the cover substrate 50. Because the circuits of the modular multilayer ceramic wiring boards 40 are modularly connected, they can be manufactured separately. The manufactured ceramic wiring boards will go under test and only the ones with good quality will be chosen to assemble a larger size of multilayer ceramic wiring board. This is more applicable in manufacturing.

As shown in FIG. 2, the cover substrate 50 is formed on top surfaces of the multilayer ceramic wiring boards 40. The cover substrate 50 may be a ceramic substrate, a thin film substrate or a silicon substrate. In this embodiment, the cover substrate 50 is a polyimide thin-film. On a surface toward the modular multilayer ceramic wiring boards 40, the substrate 50 has a plurality contacting pads 52, and has the same contacting pad layout as the second contacting pads 42 on the modular multilayer ceramic wiring board 40. On the other surface of the cover substrate 50 contacting pads 51 are formed, such as conductive bumps which are designed according to the layout of the bonding pad 72 on the wafer 70 under test. The cover substrate 50 also has vias 53, to connect to the contacting pads 51 and 52. In another embodiment, the substrate 50 may be a silicon or ceramic substrate, with elastic probe needles or vertical probe needles manufacturing on the surface.

As shown in FIG. 3, the back plate 30, the modular multilayer ceramic wiring boards 40 and the cover substrate 50 are assembled to a probe card with full wafer contact configuration. Preferably, the back plate 30, the modular multilayer ceramic wiring board 40 and the substrate 50 should be fastened by fixtures 60. This ensured that the contacting pads 51 on the cover substrate 50 have good electrical contact with all the bonding pads 72 on wafer 70 under test for testing all the chips 71 on the wafer 70 without readjustment. The modular multilayer ceramic wiring boards 40 provide electrical connections between the contacting pads 51 on the substrate 50 and the back plate 30. Individual modular multilayer ceramic wiring board 40 could be manufactured separately and this will ensure that the probe card with full wafer contact configuration be manufactured, assembled, and applied in a more cost-effective and quality-improved way.

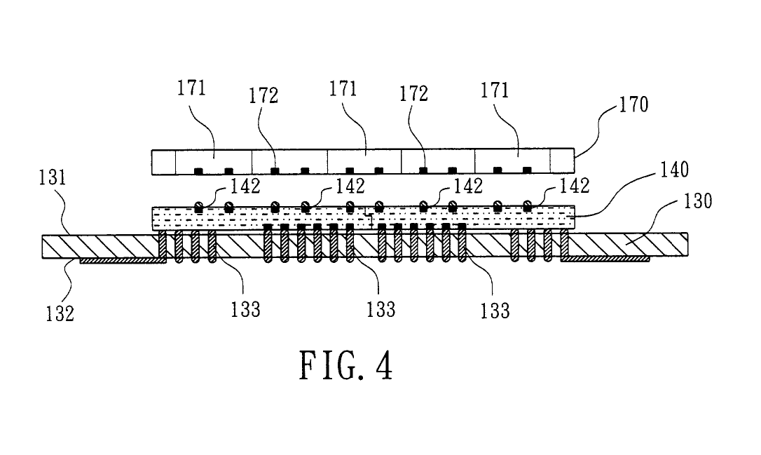

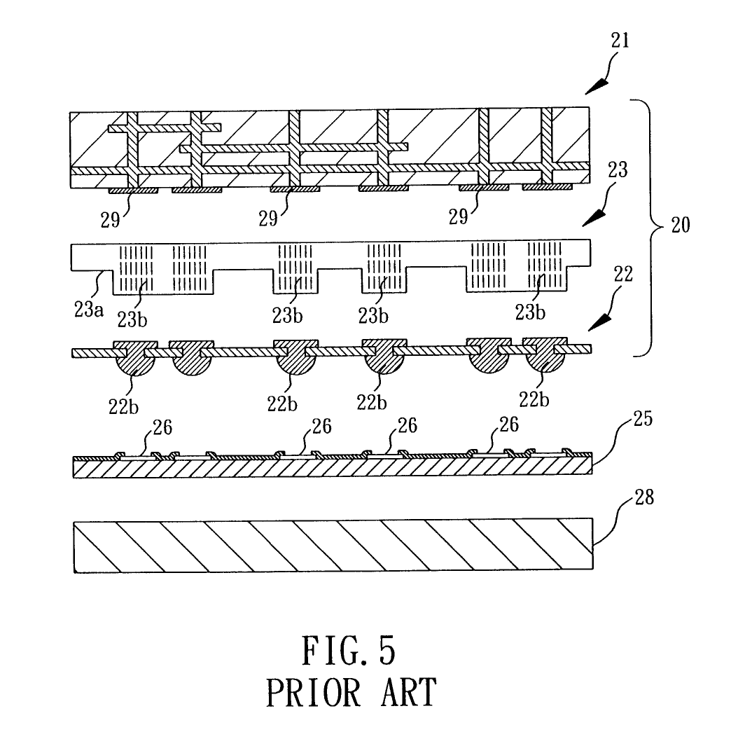

In the second embodiment of the present invention, as shown in FIG. 4, a probe card with full wafer contact configuration assembled on the semiconductor test apparatus same as the first embodiment is used for electrically contacting with another wafer 170 with larger bonding pad pitch. The bonding pad pitch of the wafer 170 is larger than that of the wafer 70 under test described above. This probe card with full wafer contact configuration comprises a back plate 130 and a plurality of modular ceramic wiring boards 140. The size of the back plate 130 is about the same as that of the back plate 30 described above. The electrical vias 133 provide electrical connection between the first surface 131 and the second surface 132. The plurality of modular ceramic wiring boards 140 are assembled with the back plate 130 to be a complete ceramic wiring board, which have contacting pads 142 formed on the exposed surfaces of the modular ceramic wiring boards 140 and connecting directly to the bonding pads 172 of the wafer 170 under test. Preferably, probe needles or electric bumps are formed on the contacting pads 142 to provide good electrical contact with all the bonding pads 172 of the wafer 170 under test. According to this present invention, the probe card not only can apply to a wafer with a smaller bonding pad pitch, but also performs chip-probing for the larger bonding pad pitch. This increases the flexibility of the apparatus, and it needs only one chip probing during the processing. It does not need to perform electrical contact or alignment several times.

The above description of embodiments of this invention is intended to be illustrative and not limiting. Other embodiments of this invention will be obvious to those skilled in the art in view of the above disclosure.

What is claimed is:

1. A probe card with full wafer contact configuration comprising:
a back plate;
a plurality of modular multilayer ceramic wiring boards patterned with multilayer circuits and assembled on the back plate on a same plane; and
a cover substrate having a plurality of contact pads for contacting bonding pads on a wafer under test, wherein the contact pads on the cover substrate are electrically coupled to the back plate through the modular multilayer ceramic wiring boards.

2. The probe card according to claim 1, wherein the total size of the modular multilayer ceramic wiring boards is larger than that of the wafer under test.

3. The probe card according to claim 1, wherein the cover substrate is a thin film.

4. The probe card according to claim 1, wherein the cover substrate is a ceramic wiring board or silicon wiring board.

5. The probe card according to claim 1, wherein the cover substrate has vias.

6. The probe card according to claim 1, further comprising a plurality of probe needles on the contacting pads of the cover substrate.

7. The probe card according to claim 1, further comprising a plurality of conductive bumps on the contacting pads of the cover substrate.

8. A probe card with full wafer contact configuration, comprising:
a back plate; and
a plurality of modular ceramic wiring boards patterned with multilayer circuits, wherein the plurality of modular ceramic wiring boards are coplanarly mounted on the back plate, a plurality of contacting pads are formed on exposed surfaces of the modular ceramic wiring boards and are electrically coupled to the back plate for connecting directly to bonding pads of a wafer under test.

9. The probe card according to claim 8, wherein the total size of the modular ceramic wiring boards is larger than that of the wafer under test.

10. The probe card according to claim 8, further comprising a plurality of probe needles on the contacting pads of the modular ceramic wiring boards.

11. The probe card according to claim 8, further comprising a plurality of conductive bumps on the contacting pads of the modular ceramic wiring boards.
